(19) United States
(12) Patent Application Publication
(10) Pub. No.: US 2018/0203274 A1
(43) Pub. Date: Jul. 19, 2018

(54) DISPLAY DEVICE AND DRIVING DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventor: Pengtao LI, Beijing (CN)

(21) Appl. No.: 15/534,244

(22) PCT Filed: Feb. 3, 2017
(86) PCT No.: PCT/CN2017/072807

§ 371 Date: Jun. 8, 2017

(30) Foreign Application Priority Data
May 13, 2016 (CN) 201610319544.3

(51) Int. Cl. G02F 1/133; G02F 1/1362; H01L 27/12; G02F 1/1333

(52) U.S. Cl. CPC G02F 1/13306; G02F 1/136286; G09G 2310/0264; G02F 1/133308; H01L 27/124

(57) ABSTRACT

The present application provides a display device and a driving device. The display device comprises a driving device and a display panel, the display panel comprises a plurality of gate control lines, a plurality of gate lines and a plurality of data lines, the gate lines and the data lines are intersected to define pixels, the driving device comprises a driving circuit, and gate output pins and source output pins provided on the driving circuit; connection ends of the data lines are connected to the corresponding source output pins, the gate lines are connected to the corresponding gate control lines, connection ends of the gate control lines are connected to the corresponding gate output pins, and the connection ends of the gate control lines and the connection ends of the data lines are connected to a same side of the driving circuit.

### FIELD

The present application relates to a field of display technology, and particularly, to a display device and a driving device.

### BACKGROUND

With a development of display technology, a liquid crystal display device is used more and more widely. However, there are following problems in existing solutions of prior art: gate control lines and data lines are connected to different sides of a driving circuit, the gate control lines are generally connected to right and left sides of the driving circuit, resulting in large fan-out areas at right and left sides of a display panel, thereby causing a display device comprising the display panel to have wide bezels.

### SUMMARY

An object of the present application is to provide a display device and a driving device for achieving narrow bezels of the display device.

In order to achieve above object, the present application provides a display device comprising a driving device and a display panel, the display panel comprising a plurality of gate control lines, a plurality of gate lines and a plurality of data lines, the gate lines and the data lines being intersected to define pixels, the driving device comprising a driving circuit, and gate output pins and source output pins provided on the driving circuit;
connection ends of the data lines are connected to the corresponding source output pins;
the gate lines are connected to the corresponding gate control lines, connection ends of the gate control lines are connected to the corresponding gate output pins, and the connection ends of the gate control lines and the connection ends of the data lines are connected to a same side of the driving circuit.

Optionally, the connection ends of the gate control lines are connected to a side of the driving circuit proximal to the display panel, and the connection ends of the data lines are also connected to the side of the driving circuit proximal to the display panel.

Optionally, all the gate output pins and the source output pins are provided at the side of the driving circuit proximal to the display panel.

Optionally, the gate lines and the gate control lines are provided in a same layer.

Optionally, the gate control lines and the data lines are provided in parallel.

Optionally, the gate lines are arranged sequentially, and the gate control lines connected to the gate lines are also arranged sequentially.

Optionally, the gate lines are arranged sequentially, and the gate control lines connected to the gate lines are arranged non-sequentially in accordance with a shape of the display panel.

Optionally, the gate control lines and the data lines are provided in parallel, and the gate control lines and the data lines are provided alternatively.

Optionally, the gate control lines and the data lines are provided in parallel, and one of the gate control lines is provided every multiple data lines.

Optionally, the display panel is of a singular shape.

In order to achieve the above object, the present application further provides a driving device of a display device, the display device comprising a plurality of gate control lines, a plurality of gate lines and a plurality of data lines, the gate lines and the data lines are intersected to define pixels, the driving device comprising a driving circuit, and gate output pins and source output pins provided on the driving circuit,
the gate output pins are connected to connection ends of the corresponding gate control lines, the gate control lines are connected to the corresponding gate lines;
the source output pins are connected to connection ends of the corresponding data lines, all connection ends of the gate control lines and the connection ends of the data lines are connected to a same side of the driving circuit.

Optionally, the gate output pins and the source output pins are provided at a side of the driving circuit proximal to the display panel.

Optionally, the gate output pins and the source output pins are provided alternatively.

Optionally, one of the gate output pins is provided every multiple source output pins.

The present application has following beneficial effects.

In technical solutions of the display device and the driving device provided by the present application, the connection ends of the data lines are connected to the corresponding source output pins, the gate lines are connected to the corresponding gate control lines, the connection ends of the gate control lines are connected to the corresponding gate output pins, and all the connection ends of the gate control lines and the connection ends of the data lines are connected to a same side (i.e., the side of the driving circuit proximal to the display panel) of the driving circuit, avoiding the connection ends of the gate control lines and the connection ends of the data lines being connected to different sides of the driving circuit, resulting in reduced fan-out areas at right and left sides of the display panel, thereby the display device has narrow bezels.

### BRIEF DESCRIPTION OF THE DRAWINGS

FIG. 1 shows a structural diagram of a liquid crystal display device;

FIG. 2 shows a structural diagram of a display device in a first embodiment of the present application;

FIG. 3 shows a diagram of gate output pins and source output pins in the first embodiment;

FIG. 4 shows another structural diagram of the display device in the first embodiment;

FIG. 5 shows a structural diagram of a display device in a second embodiment of the present application;

FIG. 6 shows a structural diagram of a display device in a third embodiment of the present application;

FIG. 7 shows a structural diagram of a display device in a fourth embodiment of the present application.

### DETAILED DESCRIPTION OF THE EMBODIMENTS

In order to make a person skilled in the art understand technical solutions of the present application better, the display device and the driving device provided by the present application will be described in detail below in conjunction with accompanying drawings.

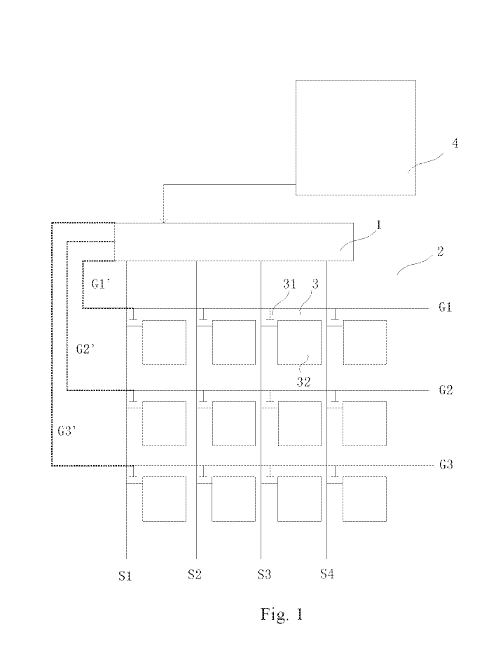

FIG. 1 shows a structural diagram of a liquid crystal display device. As shown in FIG. 1, the liquid crystal display device comprises a driving circuit 1 and a display panel 2, the display panel 2 comprises a plurality of gate control lines, a plurality of gate lines and a plurality of data lines, the gate lines and the data lines are intersected to define pixels 3, each of the pixels 3 comprises a thin film transistor 31 and a pixel electrode 32, the gate lines include gate lines G1, G2, G3, . . . , Gn, the data lines include data lines S1, S2; S3, S4, . . . , Sn, the gate control lines include gate control lines G1′, G2′, G3′, . . . , Gn′, only the gate lines G1, G2, G3, the data lines S1, S2; S3, S4 and the gate control lines G1′, G2′, G3′ are shown in FIG. 1. In order to clearly show a difference between the gate control lines and the gate lines, the gate control lines are drawn by dotted lines, the gate lines are connected to the driving circuit 1 through the corresponding gate control lines, the gate control lines are connected to a left side of the driving circuit 1, thus a fan-out area is formed at the left side of the display panel 2 by the gate control lines. The data lines are connected to a side of the driving circuit 1 proximal to the pixels 3. The driving circuit 1 of prior art is of a one-chip structure, thus the driving circuit 1 can drive a gate of the thin film transistor 31 through the gate line and drive a source of the thin film transistor through the data line. Similarly, the gate control lines may also be provided at a right side of the driving circuit 1, which will not be shown in a figure.

However, in above technical solution, the gate control lines and the data lines are connected to different sides of the driving circuit 1, the gate control lines are generally connected to left and right sides of the driving circuit 1, resulting in large fan-out areas at left and right sides of the display panel 2, thereby causing the display device to have wide bezels.

FIG. 2 shows a structural diagram of a display device in a first embodiment of the present application. As shown in FIG. 2, the display device comprises a driving device and a display panel 2, the display panel 2 comprises a plurality of gate control lines, a plurality of gate lines and a plurality of data lines, the gate lines and the data lines are intersected to define pixels 3, the driving device comprises a driving circuit 1, and gate output pins and source output pins provided on the driving circuit 1, connection ends of the data lines are connected to the corresponding source output pins, the gate lines are connected to the corresponding gate control lines, connection ends of the gate control lines are connected to the corresponding gate output pins, and the connection ends of the gate control lines and the connection ends of the data lines are connected to a same side (i.e., the side of the driving circuit 1 proximal to the display panel 2) of the driving circuit 1, wherein, the connection ends of the data lines are connected to the source output pins of the driving circuit 1, and the connection ends of the gate control lines are connected to the gate output pins of the driving circuit 1.

In the present embodiment, the gate lines may include gate lines G1, G2, G3, . . . , Gn, the data lines include data lines S1, S2, S3, S4, . . . , Sn, only the gate lines G1, G2, G3 and the data lines S1, S2, S3, S4 are shown in FIG. 2. The gate control lines and the gate lines are provided correspondingly, optionally, each of the gate lines corresponds to one of the gate control lines, thus a plurality of gate control lines are provided, and the gate control lines may include gate control lines G1′, G2′, G3′, . . . , Gn′, only the gate control lines G1′, G2′, G3′ are shown in FIG. 2. Seen from FIG. 2, the gate line G1 corresponds to the gate control line G1′, thus the gate line G1 is connected to the gate control line G1′, the gate control line G1′ is connected to the corresponding gate output pin on the driving circuit 1, thus the gate line G1 is connected to the driving circuit 1 through the gate control line G1′ and the corresponding gate output pin; the gate line G2 corresponds to the gate control line G2′, the gate line G2 is connected to the gate control line G2′, the gate control line G2′ is connected to the corresponding gate output pin on the driving circuit 1, thus the gate line G2 is connected to the driving circuit 1 through the gate control line G2′ and the corresponding gate output pin; the gate line G3 corresponds to the gate control line G3′, the gate line G3 is connected to the gate control line G3′, the gate control line G3′ is connected to the corresponding gate output pin on the driving circuit 1, thus the gate line G3 is connected to the driving circuit 1 through the gate control line G3′ and the corresponding gate output pin. In order to clearly show a difference between the gate control lines and the gate lines, the gate control lines in FIG. 2 are drawn by dotted lines.

As shown in FIG. 2, the driving circuit 1 has four sides, the connection ends of the data lines are connected to a side of the driving circuit 1 proximal to the display panel 2, the connection ends of the gate control lines are also connected to the side of the driving circuit 1 proximal to the display panel 2, that is, the connection ends of the gate control lines and the connection ends of the data lines are connected to a same side of the driving circuit 1.

Optionally, the gate lines and the gate control lines are provided in a same layer. During manufacturing the gate lines, the gate control lines may be formed synchronously so that the gate lines and the gate control lines are formed in the same layer, thus the manufacturing cost is reduced.

Optionally, the gate control lines and the data lines are provided in parallel. In the present embodiment, the data lines are provided in parallel, the gate control lines are provided in parallel, and the data lines and the gate control lines are also provided in parallel. Such configuration facilitates an arrangement of the gate control lines, resulting in a reduced complexity of wiring in the display panel.

In the present embodiment, the gate lines are arranged sequentially, and the gate control lines connected to the gate lines are also arranged sequentially. As shown in FIG. 2, the gate lines G1, G2, G3 are arranged sequentially from top to bottom, and the gate lines are provided in parallel, the gate control lines G1′, G2′, G3′ are arranged sequentially from left to right.

In the present embodiment, the gate control lines and the data lines are provided alternatively. As shown in FIG. 2, the gate control lines and the data lines are arranged in an order of G1′, S1, G2′, S2, G3′ and S3.

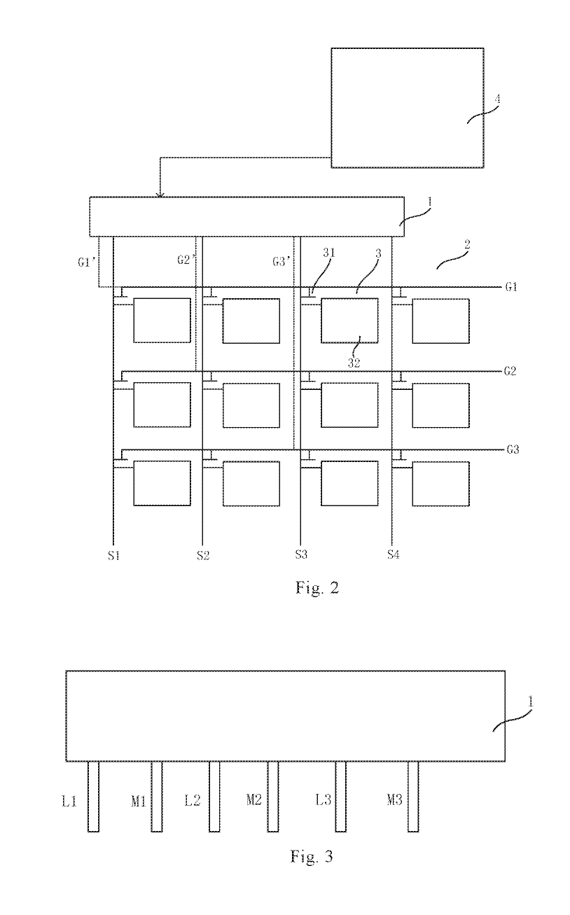

FIG. 3 shows a diagram of the gate output pins and the source output pins in the first embodiment. As shown in FIG. 3, the driving circuit 1 is provided with the gate output pins and the source output pins thereon, the gate output pins and the source output pins are located at a same side (i.e., the side of the driving circuit 1 proximal to the display panel 2) of the driving circuit 1. Optionally, the number of the gate output pins is the same as that of the gate control lines, and the number of the source output pins is the same as that of the data lines. The gate output pins may include gate output pins L1, L2, L3, . . . , Ln, the source output pins may include source output pins M1, M2, M3, . . . , Mn, and only the gate output pins L1, L2, L3 and the source output pins M1, M2, M3 are shown in FIG. 3. Optionally, each of the gate control lines corresponds to one of the gate output pins, each of the data lines corresponds to one of the source output pins, as shown in FIGS. 2 and 3, the gate output pin L1 corresponds to the gate control line G1′, the gate output pin L2 corresponds to the gate control line G2′, the gate output pin L3 corresponds to the gate control line G3′, the source output pin M1 corresponds to the data line S1, the source output pin M2 corresponds to the data line S2, and the source output pin M3 corresponds to the data line S3. The gate control line G1′ is connected to the gate output pin L1 so that the gate control line G1′ is connected to the driving circuit 1 through the corresponding gate output pin L1; the gate control line G2′ is connected to the gate output pin L2 so that the gate control line G2′ is connected to the driving circuit 1 through the corresponding gate output pin L2; the gate control line G3′ is connected to the gate output pin L3 so that the gate control line G3′ is connected to the driving circuit 1 through the corresponding gate output pin L3. The data line S1 is connected to the source output pin M1 so that the data line S1 is connected to the driving circuit 1 through the corresponding source output pin M1; data line S2 is connected to the source output pin M2 so that the data line S2 is connected to the driving circuit 1 through the corresponding source output pin M2; the data line S3 is connected to the source output pin M3 so that the data line S3 is connected to the driving circuit 1 through the corresponding source output pin M3. As shown in FIGS. 2 and 3, in the present embodiment, the gate output pins are located at the side of the driving circuit 1 proximal to the display panel 2 so that the gate control lines are connected to the side of the driving circuit 1 proximal to the display panel 2; the source output pins are located to the side of the driving circuit 1 proximal to the display panel 2 so that the data lines are connected to the side of the driving circuit 1 proximal to the display panel 2.

In the present embodiment, the gate output pins and the source output pins are provided alternatively. As shown in FIG. 3, the gate output pins and the source output pins are provided from left to right in an order of L1, M1, L2, M2, L3 and M3. Such configuration facilitates connections between the gate lines and the gate control lines, thus simplifying the structure of the display panel and reducing the complexity of process.

In the present embodiment, each of the pixels 3 comprises the thin film transistor 31 and the pixel electrode 32. The thin film transistor 31 may comprise a gate, an active layer, a source and a drain, each of the gate lines is connected to the gate of the corresponding thin film transistor 31, each of the data lines is connected to the source of the corresponding thin film transistor 31. The pixel electrode 32 is connected to the drain of the thin film transistor 31.

In the present embodiment, the driving circuit 1 is of a structure of one-chip, and functions of a gate driving circuit and a source driving circuit are integrated in the driving circuit 1, thus the driving circuit 1 can drive the gates of the thin film transistors 31 through the gate lines and drive the sources of the thin film transistors through the data lines.

The display device may further comprise a timing controller 4 for outputting a timing control signal to the driving circuit 1.

FIG. 4 shows another structural diagram of the display device in the first embodiment. As shown in FIG. 4, the gate lines G1, G2, G3 are arranged sequentially from top to bottom, and the gate control lines G1′, G2′, G3′ are arranged sequentially from right to left.

Optionally, in the present embodiment, the display device is a liquid crystal display device. In practical applications, the display device may be applied in a vehicular field, that is, the display device may he a vehicle display device.

In technical solutions of the display device provided by the present embodiment, the connection ends of the data lines are connected to the corresponding source output pins, the gate lines are connected to the corresponding gate control lines, the connection ends of the gate control lines are connected to the corresponding gate output pins, and all the connection ends of the gate control lines and the connection ends of the data lines are connected to a same side (i.e., the side of the driving circuit proximal to the display panel) of the driving circuit, avoiding the connection ends of the gate control lines and the connection ends of the data lines being connected to different sides of the driving circuit, resulting in reduced fan-out areas at right and left sides of the display panel, thereby the display device has narrow bezels. The display deice of the present embodiment may also be bezel-less. In the display device of the present embodiment, the wiring of the gate control lines is simple, reducing the complexity of process and resulting in a good yield and a high reliability of the display device.

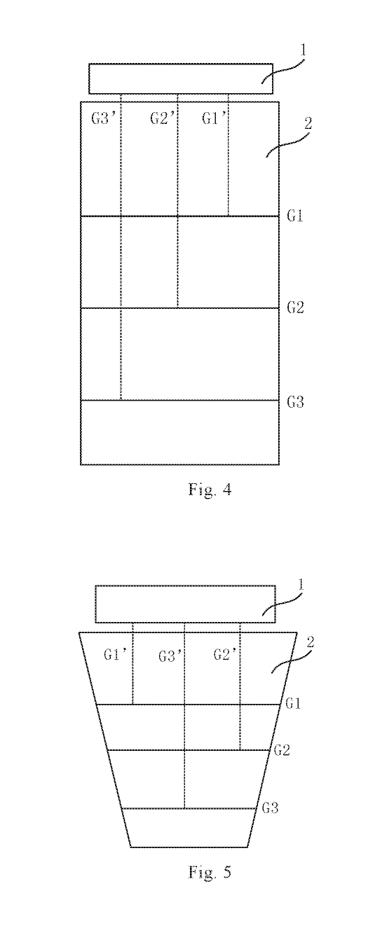

FIG. 5 shows a structural diagram of a display device in a second embodiment of the present application. As shown in FIG. 5, there is a difference between the present embodiment and the first embodiment that, the gate control lines connected to the gate lines are arranged non-sequentially in accordance a shape of the display panel.

In the present embodiment, the display panel 2 may be of a singular shape, for example, when the display panel 2 is not a square or rectangle, the display panel 2 may be referred to as a display panel with a singular shape. The display panel 2 in FIG. 5 is of an inverted trapezoid. The gate control lines G1′, G2′, G3′ are described by referring to FIG. 5. As shown in FIG. 5, the gate control line G1′ is connected to the gate line the gate control line G2′ is connected to the gate line G2, the gate control line G3′ is connected to the gate line G3, the gate control lines are provided from left to right in an order of G1′, G3′ and G2′.

In technical solutions of the display device provided by the present embodiment, the connection ends of the data lines are connected to the corresponding source output pins, the gate lines are connected to the corresponding gate control lines, the connection ends of the gate control lines are connected to the corresponding gate output pins, and all the connection ends of the gate control lines and the connection ends of the data lines are connected to a same side (i.e., the side of the driving circuit proximal to the display panel) of the driving circuit, avoiding the connection ends of the gate control lines and the connection ends of the data lines being connected to different sides of the driving circuit, resulting in reduced fan-out areas at right and left sides of the display panel, thereby the display device has narrow bezels. The display deice of the present embodiment may also have bezels with a singular shape. In the display device of the present embodiment, the wiring of the gate control lines is simple, reducing the complexity of process and resulting in a good yield and a high reliability of the display device.

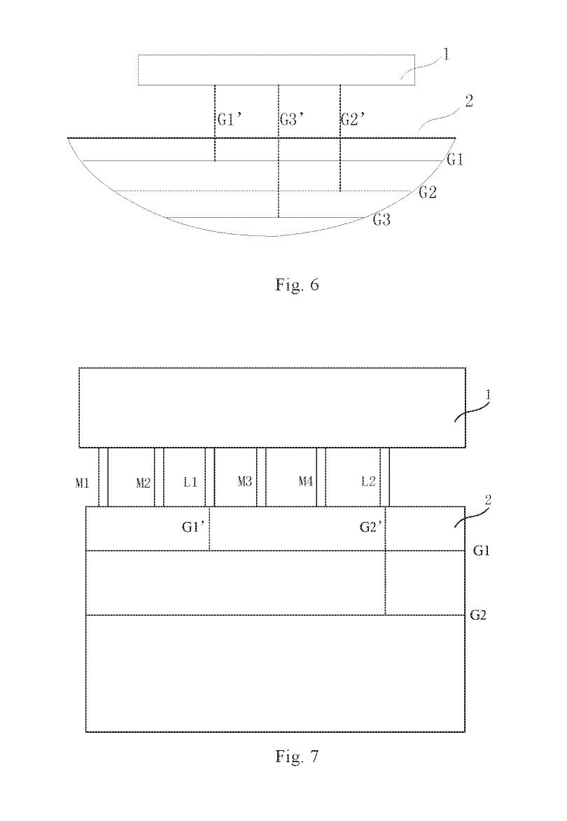

FIG. 6 shows a structural diagram of a display device in a third embodiment of the present application. As shown in FIG. 6, there is a difference between the present embodiment and the second embodiment that, the display panel 2 in the present embodiment is of a semicircle.

In technical solutions of the display device provided by the present embodiment, the connection ends of the data lines are connected to the corresponding source output pins, the gate lines are connected to the corresponding gate control lines, the connection ends of the gate control lines are connected to the corresponding gate output pins, and all the connection ends of the gate control lines and the connection ends of the data lines are connected to a same side (i.e., the side of the driving circuit proximal to the display panel) of the driving circuit, avoiding the connection ends of the gate control lines and the connection ends of the data lines being connected to different sides of the driving circuit, resulting in reduced fan-out areas at right and left sides of the display panel, thereby the display device has narrow bezels. The display deice of the present embodiment may also be bezel-less. In the display device of the present embodiment, the wiring of the gate control lines is simple, reducing the complexity of process and resulting in a good yield and a high reliability of the display device.

FIG. 7 shows a structural diagram of a display device in a fourth embodiment of the present application. As shown in FIG. 7, there is a difference between the present embodiment and the first embodiment that, one of the gate control lines is provided every multiple data lines, one of the gate output pins is provided every multiple source output pins.

As shown in FIG. 7, one of the gate output pins is provided every two source output pins. For example, the source output pins and the gate output pins in FIG. 7 are provided from left to right in an order of M1, M2, L1, M3, M4 and L2.

It should be noted that, the display panel 2 in FIG. 7 only shows the gate lines G1, G2 and the gate control lines G1′, G2′, other structures are not shown.

In the present application, positions of the gate output pins and the source output pins and the numbers thereof may be determined in accordance with resolution of the display device. Thus, the positions of the gate output pins and the sources output pins and the numbers thereof may be different between display devices with different resolutions.

In technical solutions of the display device provided by the present embodiment, the connection ends of the data lines are connected to the corresponding source output pins, the gate lines are connected to the corresponding gate control lines, the connection ends of the gate control lines are connected to the corresponding gate output pins, and all the connection ends of the gate control lines and the connection ends of the data lines are connected to a same side (i.e., the side of the driving circuit proximal to the display panel) of the driving circuit, avoiding the connection ends of the gate control lines and the connection ends of the data lines being connected to different sides of the driving circuit, resulting in a reduced fan-out areas at right and left sides of the display panel, thereby the display device has narrow bezels. The display deice of the present embodiment may also be bezel-less. In the display device of the present embodiment, the wiring of the gate control lines is simple, reducing the complexity of process and resulting in a good yield and a high reliability of the display device.

A fifth embodiment of the present application provides a driving device. As shown in FIG. 3, the driving device comprises the driving circuit 1, and the gate output pins and the source output pins provided on the driving circuit 1. The gate output pins are connected to the connection ends of the corresponding gate control lines, the gate control lines are connected to the corresponding gate lines; the source output pins are connected to connection ends of the corresponding data lines, all connection ends of the gate control lines and the connection ends of the data lines are connected to a same side of the driving circuit 1.

In the present embodiment, the gate output pins are connected to the corresponding gate control lines, and the source output pins are connected to the corresponding data lines. Optionally, the number of the gate output pins is the same as that of the gate control lines, and the number of the source output pins is the same as that of the data lines. The gate output pins may include gate output pins L1, L2, L3, . . . , Ln, the source output pins may include M1, M2, M3, . . . , Mn, and only the gate output pins L1, L2, L3 and the source output pins M1, M2, M3 are shown in FIG. 3.

In the present embodiment, the gate output pins and the source output pins are provided alternatively, As shown in FIG. 3, the gate output pins and the source output pins are provided from left to right in an order of L1, M1, L2, M2, L3 and M3. Such configuration facilitates connections between the gate lines and the gate control lines, thus simplifying the structure of the display panel and reducing the complexity of process.

In practical applications, optionally, one of the gate output pins is provided every multiple source output pins, which will not be shown.

In technical solutions of the display device provided by the present embodiment, the connection ends of the data lines are connected to the corresponding source output pins, the gate lines are connected to the corresponding gate control lines, the connection ends of the gate control lines are connected to the corresponding gate output pins, and all the connection ends of the gate control lines and the connection ends of the data lines are connected to a same side (i.e., the side of the driving circuit proximal to the display panel) of the driving circuit, avoiding the connection ends of the gate control lines and the connection ends of the data lines being connected to different sides of the driving circuit, resulting in reduced fan-out areas at right and left sides of the display panel, thereby the display device has narrow bezels.

It should be understood that, the above embodiments are merely exemplary embodiments for explaining principle of the present application, but the present application is not limited thereto. Various modifications and improvements may be made by those ordinary skilled in the art within the spirit and essence of the present application, these modifications and improvements fall into the protection scope of the present application.

1. A display device, comprising a driving device and a display panel, the display panel comprising a plurality of gate control lines, a plurality of gate lines and a plurality of data lines, the gate lines and the data lines being intersected to define pixels, the driving device comprising a driving circuit, and gate output pins and source output pins provided on the driving circuit;
connection ends of the data lines are connected to the corresponding source output pins, the gate lines are connected to the corresponding gate control lines, connection ends of the gate control lines are connected to the corresponding gate output pins, and the connection ends of the gate control lines and the connection ends of the data lines are connected to a same side of the driving circuit.

2. The display device of claim 1, wherein the connection ends of the gate control lines are connected to a side of the driving circuit proximal to the display panel, and the connection ends of the data lines are also connected to the side of the driving circuit proximal to the display panel.

3. The display device of claim 2, wherein all the gate output pins and the source output pins are provided at the side of the driving circuit proximal to the display panel.

4. The display device of claim 1, wherein the gate lines and the gate control lines are provided in a same layer.

5. The display device of claim 1, wherein the gate control lines and the data lines are provided in parallel.

6. The display device of claim 1, wherein the gate lines are arranged sequentially, and the gate control lines connected to the gate lines are also arranged sequentially.

7. The display device of claim 1, wherein the gate lines are arranged sequentially, and the gate control lines connected to the gate lines are arranged non-sequentially in accordance with a shape of the display panel.

8. The display device of claim 1, wherein the gate control lines and the data lines are provided in parallel, and the gate control lines and the data lines are provided alternatively.

9. The display device of claim 1, wherein the gate control lines and the data lines are provided in parallel, and one of the gate control lines is provided every multiple data lines.

10. The display device of claim 1, wherein the display panel is of a singular shape.

11. A driving device of a display device, the display device comprises a display panel, the display panel comprises a plurality of gate control lines, a plurality of gate lines and a plurality of data lines, the gate lines and the data lines are intersected to define pixels, the driving device comprising a driving circuit, and gate output pins and source output pins provided on the driving circuit,
the gate output pins are connected to connection ends of the corresponding gate control lines, the gate control lines are connected to the corresponding gate lines;
the source output pins are connected to connection ends of the corresponding data lines, all connection ends of the gate control lines and the connection ends of the data lines are connected to a same side of the driving circuit.

12. The driving device of claim 11, wherein the gate output pins and the source output pins are provided at a side of the driving circuit proximal to the display panel.

13. The driving device of claim 11, wherein the gate output pins and the source output pins are provided alternatively.

14. The driving device of claim 11, wherein one of the gate output pins is provided every multiple source output pins.
